(19) United States
(12) Patent Application Publication
(10) Pub. No.: US 2019/0058156 A1
(43) Pub. Date: Feb. 21, 2019

(54) OLED DISPLAY SUBSTRATE, MANUFACTURING METHOD THEREOF, AND OLED DISPLAY APPARATUS

(71) Applicant: BOE Technology Group Co., Ltd., Beijing (CN)

(72) Inventors: Tao Sun, Beijing (CN); Song Zhang, Beijing (CN); Youwei Wang, Beijing (CN); Tao Wang, Beijing (CN)

(21) Appl. No.: 15/964,679

(22) Filed: Apr. 27, 2018

(30) Foreign Application Priority Data
Aug. 18, 2017 (CN) 201710713140.7

(51) Int. Cl. H01L 51/52; H01L 27/32; H01L 51/56

(52) U.S. Cl. CPC H01L 51/5253; H01L 2227/323; H01L 51/56; H01L 27/3276

(57) ABSTRACT

This disclosure discloses an OLED display substrate and a manufacturing method thereof, as well as an OLED display apparatus. The OLED display substrate comprises a display area and a non-display area surrounding the display area. The OLED display substrate comprises a barrier which is provided in the non-display area and an encapsulation structure layer which covers the display area and extends to cover the barrier, and the OLED display substrate further comprises a metal halide layer which is located between the barrier and the encapsulation structure layer.

### CROSS-REFERENCE TO RELATED APPLICATION

This application claims the priority of Chinese Patent Application No. 201710713140.7 filed on Aug. 18, 2017, the contents of which are incorporated as a part of this application by reference in its entirety.

### FIELD OF THE INVENTION

This disclosure relates to the technical field of display, and particularly to an OLED (organic light-emitting diode, simply referred to as OLED) display substrate, a manufacturing method thereof, as well as an OLED display apparatus.

### BACKGROUND OF THE INVENTION

OLED display apparatuses have been regarded as the next generation display techniques which are extremely promising due to the advantages of good thinness, good lightness, wide view angle, active light emission, continuous and adjustable color of light emission, low cost, high response speed, low energy consumption, low drive voltage, wide range of operating temperature, simple production process, high light emission efficiency, flexible display, etc.

It has been demonstrated by investigations that components such as water vapor and oxygen in air have great influence on the service life of OLED devices in an OLED display apparatus. The reason is as follows. Electrons need to be injected from the cathode when an OLED device is in operation, and this requires that the lower the work function, the better; however, the cathode is typically made of metal materials such as aluminum, magnesium, calcium, and the like, and has relatively active chemical properties and is extremely prone to react with the permeated water vapor and oxygen. Furthermore, water vapor and oxygen will also be subjected to chemical reactions with the hole transport layer and the electron transport layer of the OLED device, and all of these reactions will lead to the failure of the OLED device. Therefore, the service life of the OLED device may be greatly elongated so as to elongate the useful life of the OLED display apparatus, as long as the OLED device is subjected to effective encapsulation to completely separate respective functional layers of the OLED device from water vapor, oxygen, and the like in atmosphere.

### SUMMARY OF THE INVENTION

An object of embodiments of this disclosure is to provide an OLED display substrate, a manufacturing method thereof, as well as an OLED display apparatus.

The OLED display substrate provided in an embodiment of this disclosure comprises a display area and a non-display area surrounding the display area, wherein the OLED display substrate comprises a barrier which is provided in the non-display area and an encapsulation structure layer which covers the display area and extends to cover the barrier, and the OLED display substrate further comprises a metal halide layer which is located between the barrier and the encapsulation structure layer.

Optionally, the material of the metal halide layer comprises at least one selected from a group consisting of MgF₂, AlF₃, NaF, and LiF.

Optionally, the metal halide layer has a thickness in a range of 100 Å to 1000 Å.

Optionally, an edge of the metal halide layer away from the display area extends beyond an edge of the encapsulation structure layer.

Optionally, an edge of the metal halide layer away from the display area extends beyond an edge of the encapsulation structure layer by 10 to 50 micrometers.

Optionally, the metal halide layer comprises a first part covering the display area and a second part located in the non-display area, and the second part surrounds the first part and is separated by an interval from the first part.

Optionally, the OLED display substrate further comprises a first metal wiring layer, an insulating layer, a second metal wiring layer, and a third metal wiring layer provided in order in the non-display area, wherein:

the insulating layer has a first via hole leading to the first metal wiring layer;

the second metal wiring layer is in electrical connection with the first metal wiring layer through the first via hole;

the barrier is provided on a side of the second metal wiring layer away from the insulating layer;

the third metal wiring layer is located on a side of the barrier adjacent to the display area and is in electrical connection with the second metal wiring layer;

the metal halide layer further covers the third metal wiring layer and a part of the second metal wiring layer which is not covered by the third metal wiring layer and the barrier.

Optionally, the OLED display substrate comprises a plurality of OLED devices provided in the display area and thin film transistors which are correspondingly in electrical connection with each of the OLED devices;

the first metal wiring layer is manufactured in the same layer with source and drain electrodes of the thin-film transistor;

the second metal wiring layer is manufactured in the same layer with an anode of the OLED device; and

the third metal wiring layer is manufactured in the same layer with a cathode of the OLED device.

Optionally, the insulating layer is an organic insulating layer, the second metal wiring layer has at least one second via hole leading to the organic insulating layer, and the display substrate further comprises a filling structure which is manufactured in the same layer with the barrier and fills the at least one second via hole.

Particularly, the OLED display substrate further comprises a flexible base substrate, a buffering layer, a gate insulating layer, and an interlayer insulating layer provided in order in the non-display area;

the first metal wiring layer, the insulating layer, the second metal wiring layer, the barrier, the third metal wiring layer, the metal halide layer, and the encapsulation structure layer are formed in order on the interlayer insulating layer.

An embodiment of this disclosure further provides a manufacturing method of an OLED display substrate, comprising steps of:

forming a barrier in a non-display area;

forming a metal halide layer which covers at least the barrier; and

forming an encapsulation structure layer, which covers a display area and extends to cover the barrier, on a side of the metal halide layer away from the barrier.

Particularly, the method comprises steps of:

forming a first metal wiring layer in the non-display area on a substrate;

forming an insulating layer on the first metal wiring layer, wherein the insulating layer has a first via hole leading to the first metal wiring layer;

forming a second metal wiring layer in the non-display area on the insulating layer, wherein the second metal wiring layer is in electrical connection with the first metal wiring layer through the first via hole;

forming a barrier in the non-display area on the second metal wiring layer;

forming a third metal wiring layer in the non-display area on the layered structure formed with the barrier, wherein the third metal wiring layer is located on a side of the barrier adjacent to the display area and is in electrical connection with the second metal wiring layer;

forming the metal halide layer on the third metal layer, wherein the metal halide layer covers the barrier, the third metal wiring layer, and a part of the second metal wiring layer which is not covered by the third metal wiring layer and the barrier; and

forming an encapsulation structure layer, which covers a display area and extends to cover the barrier, on the metal halide layer.

An embodiment of this disclosure further provides an OLED display apparatus, comprising the OLED display substrate of any one of technical solutions described above.

### BRIEF DESCRIPTION OF THE DRAWINGS

FIG. 1 shows a sectional schematic diagram of an OLED display substrate;

FIG. 2 shows a top view of an OLED display substrate in an embodiment of this disclosure;

FIG. 3 shows a sectional schematic diagram at A-A of FIG. 2;

FIG. 4 shows a top view of a metal halide layer in an embodiment of this disclosure; and

FIG. 5 shows a flow chart of a manufacturing method of an OLED display substrate in an embodiment of this disclosure.

### DETAILED DESCRIPTION OF THE INVENTION

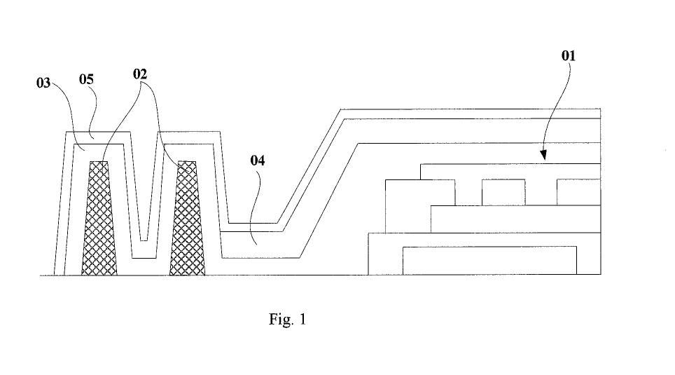

When a display substrate (the sectional structure thereof is as shown in FIG. 1) of an OLED display apparatus is produced, a TFE (thin film encapsulation, simply referred to as TFE) technique is usually used. Specific process steps are as follows: forming two barriers 02 surrounding a substrate formed with an OLED device array 01; and forming an encapsulation structure layer on the two barriers 02 and the OLED device array 01. This encapsulation structure layer comprises: a first inorganic encapsulating layer 03 formed on the two barriers 02 and the OLED device array 01, an organic encapsulating layer 04 formed on the first inorganic encapsulating layer 03, and a second inorganic encapsulating layer 05 formed on the organic encapsulating layer 04, wherein the organic encapsulating layer 04 is typically formed at the inner side of the two barriers 02 by using an IJP (ink-jet printing) process and the preliminary formation of the two barriers 02 has a barrier effect on the organic encapsulating layer 04.

In the process of implementing this disclosure, the inventor of this disclosure has found that there is a relatively large bending stress at the bend between the barrier 02 and the encapsulation structure layer when the OLED display substrate is used in a flexible OLED display apparatus or a curved OLED display apparatus, which is extremely prone to generate layer breaking or peeling, such that water vapor and oxygen enter the OLED device along seams, leading to the failure of the OLED device. Therefore, how to improve the bending reliability of the OLED display apparatus and elongate the useful life of the OLED display apparatus is a technical problem urgent to be solved at present.

In order to improve the bending reliability of the OLED display apparatus and elongate the useful life of the OLED display apparatus, the embodiments of this disclosure provide an OLED display substrate and a manufacturing method thereof, as well as an OLED display apparatus. In order to enable the objects, the technical solutions, and the advantages of this disclosure to be clearer, embodiments are exemplified below to illustrate this disclosure in further detail.

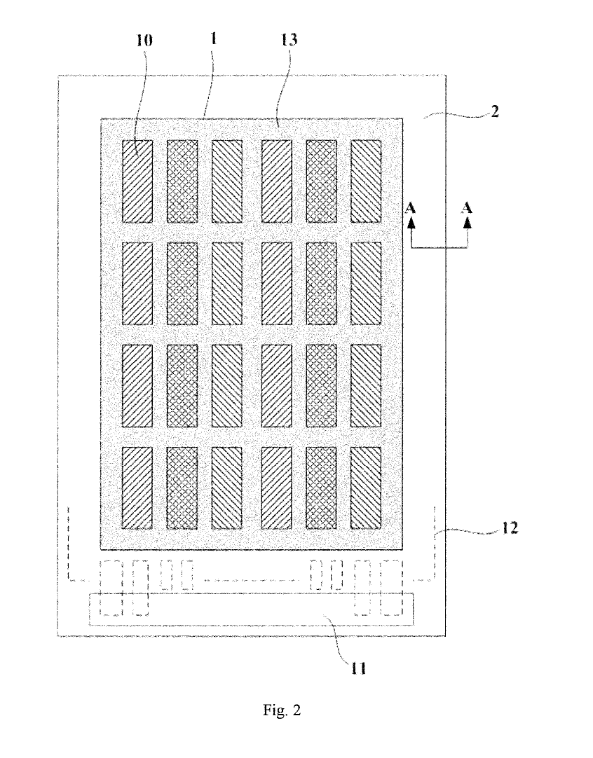

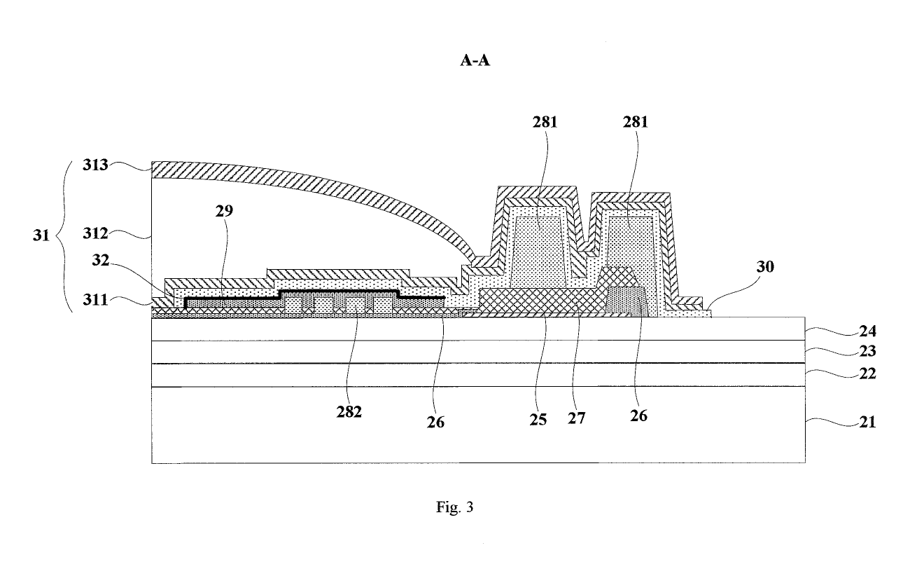

As shown in FIGS. 2 and 3, an embodiment of this disclosure provides an OLED display substrate, comprising a display area 1 and a non-display area 2 surrounding the display area 1. The OLED display substrate comprises a barrier 281 which is provided in the non-display area 2 and an encapsulation structure layer 31 which covers the display area 1 and extends to cover the barrier 281. Additionally, the OLED display substrate further comprises a metal halide layer 30 which is located between the barrier 281 and the encapsulation structure layer 31 and at least covers the barrier 281.

In the display area 1 of the OLED display substrate, there are provided a plurality of OLED devices 10 in an array arrangement and thin-film transistors which correspondingly control the operating state of each of the OLED devices 10. In the non-display area 2 of the OLED display substrate, there are provided a binding connection structure 11 and a wiring structure 12. The barrier 281, the metal halide layer 30, the encapsulation structure layer 31, and the like are used to effectively encapsulate the OLED device 10 of the display area 1, the wiring structure 12 of the non-display area 2, and the like. The main structure of the OLED device 10 comprises an anode, a cathode, and an organic light-emitting layer between the anode and the cathode. The anode and the organic light-emitting layer of each OLED device 10 are spaced from each other by a pixel defining layer 13. The cathode of each of the OLED devices 10 is connected to cathodes of a plurality of OLED devices 10 to form an integrated structure.

Typically, the barrier 281 is made of an organic material, for example polyimide, and the like. The encapsulation structure layer 31 comprises a first inorganic encapsulating layer 311, an organic encapsulating layer 312, and a second inorganic encapsulating layer 313 in order in a direction away from the flexible base substrate 21. The first inorganic encapsulating layer 311 and the second inorganic encapsulating layer 313 cover the barrier 281. The organic encapsulating layer 312 is located on the inner side of the barrier 281 adjacent to the display area.

In an embodiment of this disclosure, the specific material of the metal halide layer 30 is not limited, and for example, may include at least one of MgF₂, AlF₃, NaF, and LiF. The thickness of the metal halide layer is in a range of 100 Å to 1000 Å. By controlling the thickness of the metal halide layer in the above range, it is possible to improve the bending reliability of the OLED display apparatus and elongate the useful life of the OLED display apparatus in a better manner. The specific manner of the film forming of the metal halide layer 30 is not limited, and it is preferably formed on the substrate by an evaporation process. The evaporation process refers to heating an evaporation material under a certain vacuum condition to melt (sublimate) the evaporation into vapor composed of atoms, molecule, or atomic groups and then condensing on the substrate to form a film.

A metal halide layer 30 is added between the barrier 281 and the encapsulation structure layer 31, and the metal halide layer 30 can be closely bonded to the barrier 281, which is an organic material, and the first inorganic encapsulating layer 311, which is an inorganic material. Therefore, there are relatively good interface bonding forces between the metal halide layer 30 and the barrier 281 and between the metal halide layer 30 and the encapsulation structure layer 31 so as to reduce breaking or peeling of the edge of the OLED display substrate, and in turn water vapor and oxygen can be prevented from entering the interior of the OLED display substrate and eroding the OLED device 10. Compared to the prior art, by using the technical solutions in the embodiments of this disclosure, the bending reliability of the OLED display apparatus is improved and the useful life of the OLED display apparatus is elongated.

With reference to those as shown in FIG. 3, the OLED display substrate in this embodiment specifically comprises, in the non-display area 2, the following structures: a flexible base substrate 21, a buffering layer 22, a gate insulating layer 23, an interlayer insulating layer 24, a first metal wiring layer 25, an insulating layer 26, a second metal wiring layer 27, a barrier 281, a third metal wiring layer 29, a metal halide layer 30, and an encapsulation structure layer 31 provided in order, wherein: the insulating layer 26 has a first via hole leading to the first metal wiring layer 25; the second metal wiring layer 27 is in electrical connection with the first metal wiring layer 25 through the first via hole; the barrier 281 is provided on the side of the insulating layer 27 away from the second metal wiring layer 26; the third metal wiring layer 29 is located on the side of the barrier 281 adjacent to the display area and is in electrical connection with the second metal wiring layer 27; the metal halide layer 30 further covers the third metal wiring layer 29 and a part of the second metal wiring layer 27 which is not covered by the third metal wiring layer 29 and the barrier 281. The encapsulation structure layer 31 comprises a first inorganic encapsulating layer 311, an organic encapsulating layer 312, and a second inorganic encapsulating layer 313 in order in a direction away from the flexible base substrate 21. The first inorganic encapsulating layer 311 and the second inorganic encapsulating layer 313 cover the barrier 281. The organic encapsulating layer 312 is located on the inner side of the barrier 281 adjacent to the display area.

In an embodiment of this disclosure, optionally, the first metal wiring layer 25 is manufactured in the same layer with source and drain electrodes of the thin-film transistor; the second metal wiring layer 27 is manufactured in the same layer with an anode of the OLED device; the third metal wiring layer 29 is manufactured in the same layer with a cathode of the OLED device. The second metal wiring layer 27 may be made of a material such as ITO, and the like, and the third metal wiring layer 29 may be made of a material such as Mg, Ag, Ca, Al, MnO₃, ITO, and the like.

The first metal wiring layer 25, the second metal wiring layer 27, and the third metal wiring layer 29, which are wiring structures, are used to transmit electrical signals between electronic devices provided in the display area and control chips provided in a surrounding area. By using the solutions in the above embodiments of this disclosure, the first metal wiring layer 25, the second metal wiring layer 27, and the third metal wiring layer 29 are manufactured without additional use of a patterning process so as to simplify the process of production and save the cost of production.

Optionally, the insulating layer 26 is an organic insulating layer, the second metal wiring layer 27 has at least one second via hole leading to the organic insulating layer, and the display substrate further comprises a filling structure 282 which is manufactured in the same layer with the barrier 281 and fills the at least one second via hole. After the production of the organic insulating layer, the solvent therein is typically required to be completely volatilized, otherwise it may lead to bubbling, layering, or peeling of the substrate. By using this technical solution, the solvent in the organic insulating layer may be volatilized through the second via hole in the process of the production of the second metal wiring layer 27, and the organic insulating layer and the second metal wiring layer 27 may be manufactured sequentially and continuously so as to simplify the production process of the substrate and improve the throughput of production. The filling structure 282 fills the second via hole, which may reduce the oxidization of the second metal wiring layer 27 before the production of the third metal wiring layer 29 so as to improve the quality of the product. The filling structure 282, the barrier 281, and the pixel defining layer of the display area may be manufactured in the same layer by using the same material, for example, by using an organic material such as polyimide, and the like.

As shown in FIG. 3, the edge of the metal halide layer 30 away from the display area extends beyond the edge of the encapsulation structure layer 31. By using this design, the edge portion of the metal halide layer 30 is closely bonded to the interlayer insulating layer 24, the edge portion of the encapsulation structure layer 31 is closely bonded to the metal halide layer 30, and there is no direct bonding interface between the edge portion of the encapsulation structure layer 31 and the interlayer insulating layer 24 so as to effectively reduce the possibility of peeling therebetween and further ensure the encapsulation effect.

Optionally, the edge of the metal halide layer 30 away from the display area extends beyond the edge of the encapsulation structure layer 31 by 10 to 50 micrometers. Thus, the encapsulation effect is not only ensured, but also the production process of the metal halide layer 30 and the encapsulation structure layer 31 are relatively easily controlled.

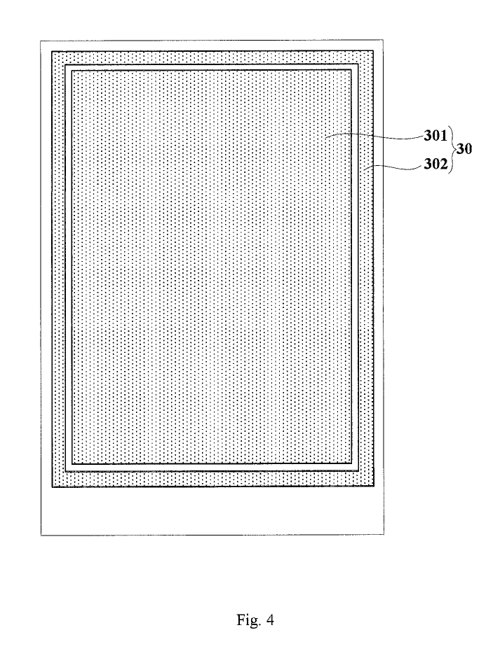

Optionally, as shown in FIG. 4, the metal halide layer 30 comprises a first part 301 covering the display area and a second part 302 located in the non-display area, and the second part 302 surrounds the first part 301 and is separated by an interval from the first part 301. The metal halide layer 30 comprises the first part 301 and the second part 302, which are disconnected, equaling that two barriers are provided. Even if a gap is generated between the first part 301 and the encapsulation structure layer 31 to allow the entrance of water vapor and oxygen, water vapor and oxygen will stop at the first part 301 and fail to further enter the display area and erode the OLED device, since the first part 301 and the second part 302 are disconnected. Additionally, since the first part 301 and the second part 302 are disconnected, the bending stress of the OLED display substrate may also be reduced so as to further improve the bending reliability of the OLED display substrate.

As shown in FIG. 3, an organic covering layer 32 (also referred to as CPL), which is used to improve the light extraction efficiency, is further provided on the upper surface of the third metal wiring layer 29 in the non-display area and the upper surface of the cathode of the OLED device in the display area.

In order to verify the effects of the embodiments of this disclosure, the inventor of this disclosure performed three interface peeling tests sequentially, which are respectively:

Test 1, an interface peeling test of an organic covering layer CPL and a silicon nitride inorganic encapsulating layer;

Test 2, an interface peeling test of an organic covering layer CPL and a silicon oxynitride inorganic encapsulating layer;

Test 3, an interface peeling test of a LiF layer and a silicon nitride inorganic encapsulating layer.

The results of the tests are as shown in Table 1:

TABLE 1
Comparison table of the results of the interface peeling tests

| | 2.0 gf/25 mm peeling test | 2.0 gf/25 mm cross-cut test |
|---|---|---|
| Test 1 | Peeled | Peeled |
| Test 2 | Peeled | Peeled |
| Test 3 | Not peeled | 5B |

As can be seen, there is a relatively good interface bonding force between the metal halide layer and the inorganic encapsulating layer, and peeling will not easily occur therebetween. Therefore, breaking or peeling of the edge of the OLED display substrate may be effectively reduced when the technical solution of the disclosure is used in an OLED display substrate.

An embodiment of this disclosure further provides an OLED display apparatus, comprising the OLED display substrate of any one of technical solutions described above. This OLED display apparatus has a relatively good bending reliability and a relatively long useful life. The specific types of the OLED display apparatus are not limited, which include but are not limited to cell phones, tablet computers, displays, and the like having a curved screen or a bendable screen.

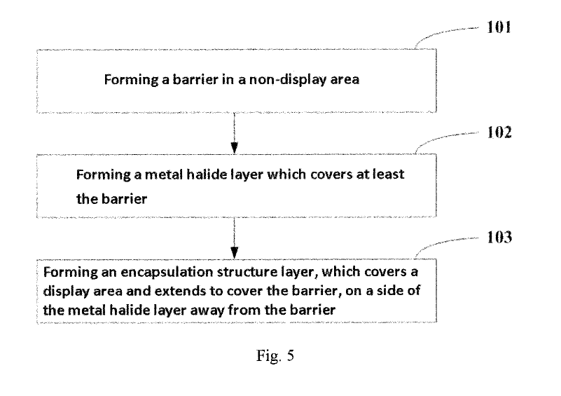

As shown in FIG. 5, an embodiment of this disclosure further provides a manufacturing method of an OLED display substrate, comprising steps of:

Step 101, forming a barrier in a non-display area; Step 102, forming a metal halide layer which covers at least the barrier; and

Step 103, forming an encapsulation structure layer, which covers a display area and extends to cover the barrier, on a side of the metal halide layer away from the barrier.

In an embodiment of this disclosure, the method described above may specifically comprise steps of:

forming a first metal wiring layer in the non-display area on a substrate;

forming an insulating layer on the first metal wiring layer, wherein the insulating layer has a first via hole leading to the first metal wiring layer;

forming a second metal wiring layer in the non-display area on the insulating layer, wherein the second metal wiring layer is in electrical connection with the first metal wiring layer through the first via hole;

forming a barrier in the non-display area on the second metal wiring layer;

forming a third metal wiring layer in the non-display area on the layered structure formed with the barrier, wherein the third metal wiring layer is located on a side of the barrier adjacent to the display area and is in electrical connection with the second metal wiring layer;

forming the metal halide layer on the third metal layer, wherein the metal halide layer covers the barrier, the third metal wiring layer, and a part of the second metal wiring layer which is not covered by the third metal wiring layer and the barrier; and

forming an encapsulation structure layer, which covers a display area and extends to cover the barrier, on the metal halide layer.

Here, before the first metal wiring layer is formed, the method described above may further comprise steps of:

forming a buffering layer, which covers the non-display area, on a flexible base substrate;

forming a gate insulating layer, which covers the non-display area, on the buffering layer; and

forming an interlayer insulating layer, which covers the non-display area, on the gate insulating layer.

The first metal wiring layer, the insulating layer, the second metal wiring layer, the barrier, the third metal wiring layer, the metal halide layer, and the encapsulation structure layer are formed in order on the interlayer insulating layer.

Here, the metal halide layer may be formed by using an evaporation process. With respect to the OLED display substrate manufactured by the method in the embodiments described above, there are relatively good interface bonding forces between the metal halide layer and the barrier and between the metal halide layer and the encapsulation structure layer so as to reduce breaking or peeling of the edge of the OLED display substrate, and in turn water vapor and oxygen can be prevented from entering the interior of the OLED display substrate and eroding the OLED device. Therefore, by using this manufacturing method, the bending reliability of the OLED display apparatus is improved and the useful life of the OLED display apparatus is elongated.

Obviously, various modifications and variations may be made to this disclosure by the person skilled in the art without deviating from the spirit and the scope of this disclosure. Thus, if these modifications and variations of this disclosure are within the scope of the claims of this disclosure and equivalent techniques thereof, this disclosure also intends to encompass these modifications and variations.

What is claimed is:

1. An OLED display substrate, comprising a display area and a non-display area surrounding the display area, wherein the OLED display substrate comprises a barrier which is provided in the non-display area and an encapsulation structure layer which covers the display area and extends to cover the barrier, and
the OLED display substrate further comprises a metal halide layer which is located between the barrier and the encapsulation structure layer.

2. The OLED display substrate according to claim 1, wherein the material of the metal halide layer comprises at least one selected from a group consisting of MgF₂, AlF₃, NaF, and LiF.

3. The OLED display substrate according to claim 1, wherein the metal halide layer has a thickness in a range of 100 Å to 1000 Å.

4. The OLED display substrate according to claim 1, wherein an edge of the metal halide layer away from the display area extends beyond an edge of the encapsulation structure layer.

5. The OLED display substrate according to claim 1, wherein an edge of the metal halide layer away from the display area extends beyond an edge of the encapsulation structure layer by 10 to 50 micrometers.

6. The OLED display substrate according to claim 2, wherein an edge of the metal halide layer away from the display area extends beyond an edge of the encapsulation structure layer by 10 to 50 micrometers.

7. The OLED display substrate according to claim 3, wherein an edge of the metal halide layer away from the display area extends beyond an edge of the encapsulation structure layer by 10 to 50 micrometers.

8. The OLED display substrate according to claim 4, wherein an edge of the metal halide layer away from the display area extends beyond an edge of the encapsulation structure layer by 10 to 50 micrometers.

9. The OLED display substrate according to claim 1, wherein the metal halide layer comprises a first part covering the display area and a second part located in the non-display area, and the second part surrounds the first part and is separated by an interval from the first part.

10. The OLED display substrate according to claim 1, wherein the OLED display substrate further comprises a first metal wiring layer, an insulating layer, a second metal wiring layer, and a third metal wiring layer provided in order in the non-display area, wherein:
the insulating layer has a first via hole leading to the first metal wiring layer;
the second metal wiring layer is in electrical connection with the first metal wiring layer through the first via hole;
the barrier is provided on a side of the second metal wiring layer away from the insulating layer;
the third metal wiring layer is located on a side of the barrier adjacent to the display area and is in electrical connection with the second metal wiring layer;
the metal halide layer further covers the third metal wiring layer and a part of the second metal wiring layer which is not covered by the third metal wiring layer and the barrier.

11. The OLED display substrate according to claim 10, wherein the OLED display substrate comprises a plurality of OLED devices provided in the display area and thin film transistors which are correspondingly in electrical connection with each of the OLED devices;
the first metal wiring layer is manufactured in the same layer with source and drain electrodes of the thin-film transistor;
the second metal wiring layer is manufactured in the same layer with an anode of the OLED device; and
the third metal wiring layer is manufactured in the same layer with a cathode of the OLED device.

12. The OLED display substrate according to claim 11, wherein the insulating layer is an organic insulating layer, the second metal wiring layer has at least one second via hole leading to the organic insulating layer, and the display substrate further comprises a filling structure which is manufactured in the same layer with the barrier and fills the at least one second via hole.

13. The OLED display substrate according to claim 11, wherein the OLED display substrate further comprises a flexible base substrate, a buffering layer, a gate insulating layer, and an interlayer insulating layer provided in order in the non-display area;
the first metal wiring layer, the insulating layer, the second metal wiring layer, the barrier, the third metal wiring layer, the metal halide layer, and the encapsulation structure layer are formed in order on the interlayer insulating layer.

14. A manufacturing method of an OLED display substrate, comprising steps of:
forming a barrier in a non-display area;
forming a metal halide layer which covers at least the barrier; and
forming an encapsulation structure layer, which covers a display area and extends to cover the barrier, on a side of the metal halide layer away from the barrier.

15. The method according to claim 14, comprising steps of:
forming a first metal wiring layer in the non-display area on a substrate;
forming an insulating layer on the first metal wiring layer, wherein the insulating layer has a first via hole leading to the first metal wiring layer;
forming a second metal wiring layer in the non-display area on the insulating layer, wherein the second metal wiring layer is in electrical connection with the first metal wiring layer through the first via hole;
forming a barrier in the non-display area on the second metal wiring layer;
forming a third metal wiring layer in the non-display area on the layered structure formed with the barrier, wherein the third metal wiring layer is located on a side of the barrier adjacent to the display area and is in electrical connection with the second metal wiring layer;
forming the metal halide layer on the third metal layer, wherein the metal halide layer covers the barrier, the third metal wiring layer, and a part of the second metal wiring layer which is not covered by the third metal wiring layer and the barrier; and
forming an encapsulation structure layer, which covers a display area and extends to cover the barrier, on the metal halide layer.

16. An OLED display apparatus, comprising the OLED display substrate according to claim 1.
